(19) United States
(12) Patent Application Publication
(10) Pub. No.: US 2011/0299237 A1
(43) Pub. Date: Dec. 8, 2011

(54) MULTI-LEVEL HARD DRIVE ENCLOSURE

(76) Inventor: WEN-PENG LIANG, Fangyuan Township (TW)

(21) Appl. No.: 12/958,413

(22) Filed: Dec. 2, 2010

(30) Foreign Application Priority Data
Jun. 3, 2010 (TW) 099210514

(51) Int. Cl. H05K 5/02

(52) U.S. Cl. 361/679.38

(57) ABSTRACT

The hard drive enclosure contains a casing member where a first rack at a first lateral side has a number of partition plates, each having a number of through holes allowing a rod to pass through. A number of covers laterally arranged in parallel on a front side of the hard drive enclosure, each capable of swiveling around a front axle and engages a rod. A number of levers are pivotally configured adjacent to a back side of the first rack, each engaged by a rod and having a pushing piece. When a cover is pulled outward, a rod is engaged to drive a lever whose pushing piece ejects the hard drive for additional distance.

### TECHNICAL FIELD OF THE INVENTION

The present invention generally relates to hard drive enclosures for holding multiple hard drives, and more particular to a hard disk enclosure where the hard drive removal is further facilitated.

### DESCRIPTION OF THE PRIOR ART

A conventional hard disk enclosure usually has a casing member allowing a number of hard drives to be installed through the front and to be stacked in the casing member. To retrieve a hard drive, an elastic means at the back of the casing member helps to push the hard drive out of the casing member. For this type of enclosure, the elastic means has a complicated structure, is difficult to install, and could malfunction after a period of repeated usage so that the hard disk could not be retrieved.

### SUMMARY OF THE INVENTION

A major objective of the present invention is to provide a multi-level hard drive enclosure for accommodating a number of hard drives and, when a hard drive is to be removed, a cover is pulled open and the hard drive is automatically ejected for easy access. The hard drive enclosure has a simplified structure so that the hard drive enclosure could be manufactured with reduced cost and high life span.

The hard drive enclosure contains a casing member where a first rack at a first lateral side has a number of partition plates, each having a number of through holes allowing a rod to pass through. A number of covers laterally arranged in parallel on a front side of the hard drive enclosure, each capable of swiveling around a front axle and engages a rod. A number of levers are pivotally configured adjacent to a back side of the first rack, each engaged by a rod and having a pushing piece. When a cover is pulled outward, a rod is engaged to drive a lever whose pushing piece ejects the hard drive for additional distance.

For each cover, a curved elastic plate is configured along a back side of each cover so that, when the cover is closed, the elastic plate presses against the hard drive and, when the cover is opened, the cover is automatically swiveled open by the released elastic plate.

The foregoing objectives and summary provide only a brief introduction to the present invention. To fully appreciate these and other objects of the present invention as well as the invention itself; all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a perspective diagram showing a hard drive enclosure according an embodiment of the present invention.

FIG. 2 is a perspective schematic diagram showing the internal of the hard drive enclosure of FIG. 1.

FIG. 3 is a top-view schematic diagram showing the hard drive enclosure of FIG. 1.

FIG. 4 is perspective diagram showing a cover of the hard drive enclosure of FIG. 1 is opened.

FIG. 5 is a top-view schematic diagram showing the hard drive enclosure of FIG. 4.

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

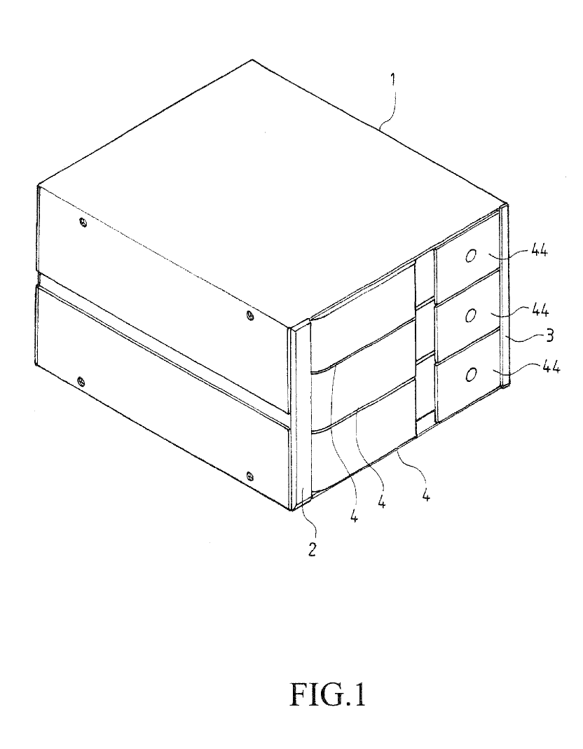

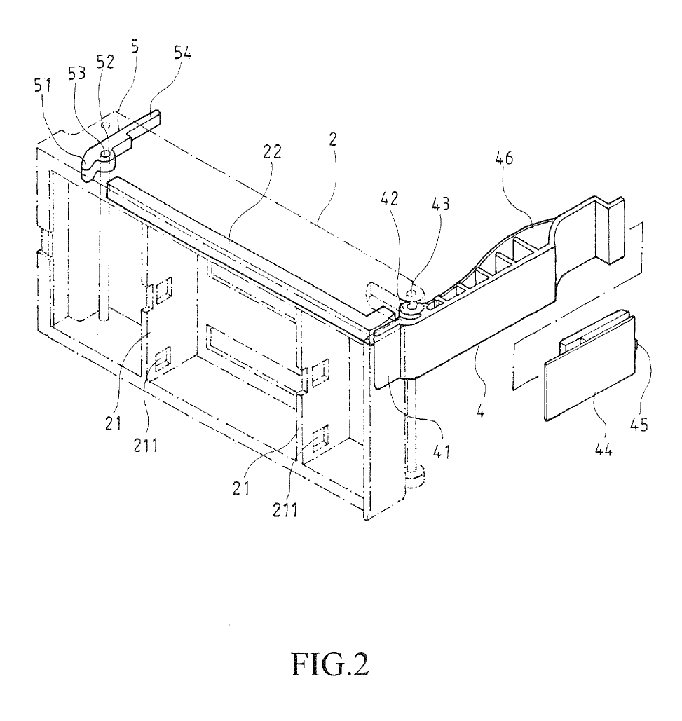

As shown in FIGS. 1 to 3, a hard drive enclosure according to an embodiment of the present invention contains a casing member 1. Inside the casing member 1, there are a first rack 2 at a first lateral side and a second rack 3 at a second lateral side opposite to the first lateral side. The first rack 2 contains a number of partition plates 21 vertically raised in parallel, each having a number of through holes 211 and each through hole 211 allowing a rod 22 to pas through.

The hard drive enclosure further contains a number of covers 4 laterally arranged in parallel on a front side of the hard drive enclosure. Each cover 4 contains an engaging piece 41 at a first end that interfaces with a rod 22, a vertical grove 42 adjacent to the engaging piece 41, a pulling piece 44 at a second end having a laterally outward protrusion 45, and an elastic plate 46 curved along a back side.

A front axle 43 is vertically configured on a front side of the first rack 2, and threads through the grooves 42 of the covers 4 so that each cover 4 is capable of swiveling around the front axle 43. A number of levers 5 are configured adjacent to a back side of the first rack 2. Each lever 5 contains a curved engaged piece 51 at a first end, a through hole 52 adjacent to the engaged piece 51, and a pushing piece 54 of appropriate length at a second end. Aback axle 53 is vertically configured adjacent to the back side of the first rack 2, and threads through the through holes 52 of the levers 5 so that each lever 5 is capable of swiveling around the back axle 53. Please note that the levers 5 provide a two-stage operation. In the first stage, a hard drive is forced out of the connection with a connector with minimum effort and, in the second stage, the pushing piece 54 pushes a hard drive for additional distance to facilitate the hard drive's retrieval.

A hard drive enclosure as described above is able to hold a number of hard drives in a vertical stack in its casing member 1 and each hard drive is sealed by a cover 4 in the front

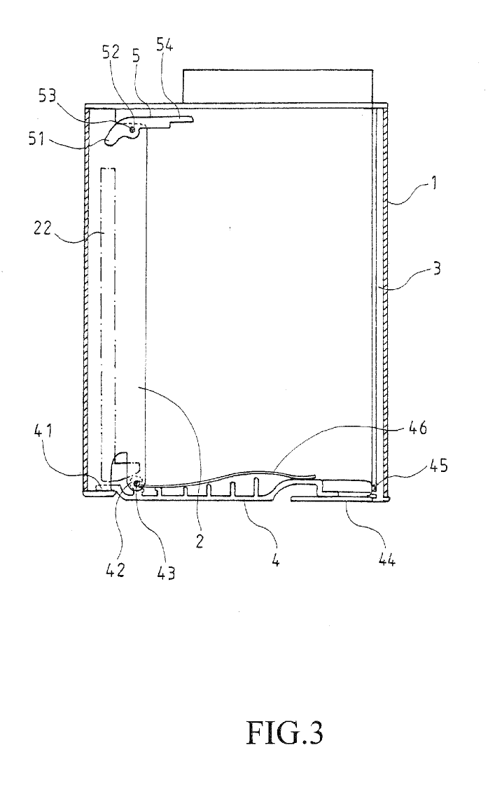

As shown in FIGS. 1 and 3, when a hard drive is slid into the casing member 1 and a cover 4 is being closed, the rod 22 is not pushed by the engaging piece 41 of the cover 4 and the corresponding lever 5 is not exerted. The hard drive therefore could be slid into the casing member 1 smoothly. When the cover 4 is closed, the protrusion 45 of the pulling piece 44 snaps into the second rack 3 so that the cover 4 is reliably locked. In the mean time, the elastic plate 46 presses against the hard drive so that the hard drive is reliably held in the casing member 1.

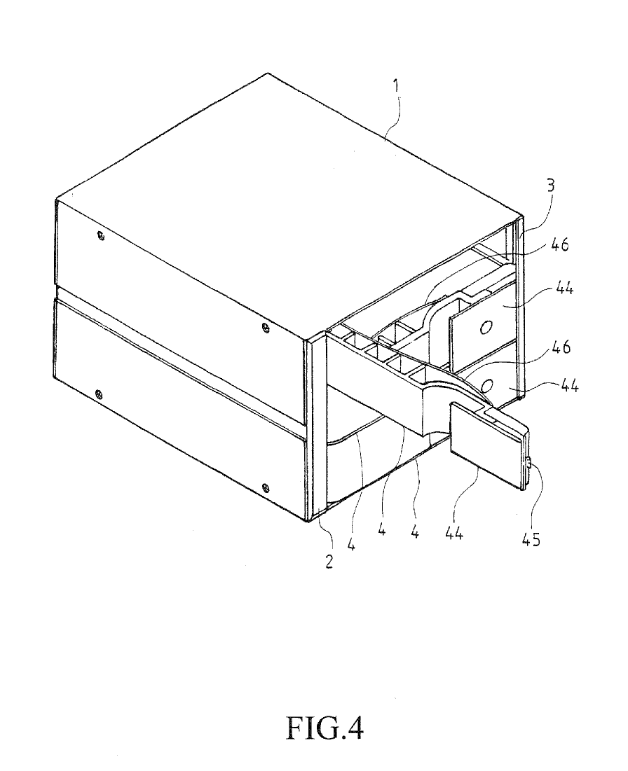

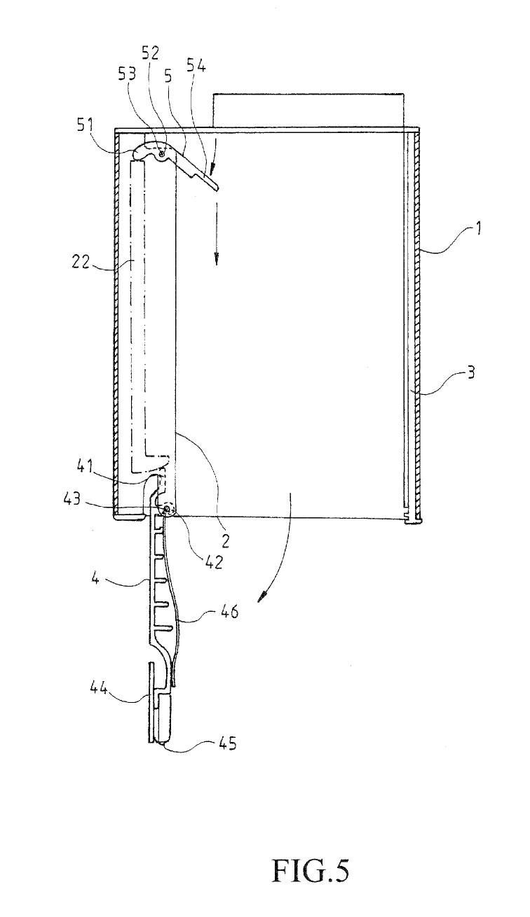

As shown in FIGS. 4 and 5, to retrieve a hard drive, a cover 4's pulling piece 44 is pulled and the protrusion 45 breaks out of the second rack 3. The pressed elastic plate 46 is as such released and the cover 4 is automatically swiveled open. As the cover 4 is further pulled aside, its engaging piece 41 drives the front end of a rod 22, and, as the rod 22 is forced to move backward through the through holes 211 of the partitioning plates 21, its back end engages the engaged piece 51 of a lever 5. Then, as the lever 5 turns, its pushing piece 54 ejects the hard drive forward out of the casing member 1 to facilitate the hard drive's access. As can be seen, the present invention has a simplified structure to sustain repeated usage for an extended life span.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. A hard drive enclosure for accommodating a plurality of hard drives, comprising:
a casing member;
a first rack at a first lateral side inside said casing member, said first rack having
a plurality of rods;
a plurality of partitioning plates raised vertically in parallel, each having a plurality of through holes allowing said rods to pass through,
a plurality of covers, each engaging a rod, arranged laterally on a front side of said casing member capable of being swiveled open and close, and
a plurality of levers, each engaged by a rod, pivotally configured adjacent to a back side of said casing member;
a second rack at a second lateral side opposing said first lateral side inside said casing member;
wherein, when a cover is pulled outward, a rod is engaged to drive a lever to ejects a hard drive out of said casing member.

2. The hard drive enclosure according to claim 1, wherein each cover contains an engaging at a first end for engaging a rod, and a vertical grove adjacent to said engaging piece; and a front axle is vertically configured on a front side of said first rack, and threads through said grooves of said covers so that each cover is capable of swiveling around said front axle.

3. The hard drive enclosure according to claim 1, wherein each lever contains a curved engaged piece at a first end and a through hole adjacent to said engaged piece; and a back axle is vertically configured adjacent to a back side of said first rack, and threads through said through holes of said levers.

4. The hard drive enclosure according to claim 3, wherein each lever contains a pushing piece at a second end for pushing a hard drive.

5. The hard drive enclosure according to claim 2, wherein each cover contains a pulling piece at a second end; each pulling piece has a laterally outward protrusion for locking said cover to said casing member.

6. The hard drive enclosure according to claim 1, wherein, for each cover, a curved elastic plate is configured along a back side of said cover so that, when said cover is closed, said elastic plate presses against a hard drive and, when said cover is opened, said cover is automatically swiveled open by the release of said elastic plate.
